(19) United States
(12) Patent Application Publication
(10) Pub. No.: US 2024/0274746 A1
(43) Pub. Date: Aug. 15, 2024

(54) CONTROL OF SURFACE MORPHOLOGY DURING THE GROWTH OF (110)-ORIENTED GAAS BY HYDRIDE VAPOR PHASE EPITAXY

(71) Applicant: Alliance for Sustainable Energy, LLC, Golden, CO (US)

(72) Inventors: Kevin Louis SCHULTE, Denver, CO (US); Wondwosen Tilahun METAFERIA, Rio Rancho, NM (US); Aaron Joseph PTAK, Littleton, CO (US); John David SIMON, Austin, TX (US)

(21) Appl. No.: 18/566,764

(22) PCT Filed: Jun. 6, 2022
(86) PCT No.: PCT/US2022/072775

§ 371 Date: Dec. 4, 2023

Related U.S. Application Data
(60) Provisional application No. 63/196,897, filed on Jun. 4, 2021.

(51) Int. Cl. H01L 31/18; C30B 25/18; C30B 25/20; C30B 29/40; C30B 29/42; H01L 31/0735

(52) U.S. Cl. CPC H01L 31/1844; C30B 25/18; C30B 25/20; C30B 29/40; C30B 29/42; H01L 31/0735

(57) ABSTRACT

Disclosed herein are methods for the growth of (110) GaAs solar cells by hydride vapor phase epitaxy (HVPE) as an advance towards a (110)-oriented device platform with substrate reuse via spalling. Controlled spalling offers a fracture-based path to substrate amortization, allowing device removal and substrate reuse, but the faceted surface generated in spalling of (100)-GaAs presents hurdles to direct regrowth of subsequent devices. Spalling of (110)-oriented substrates takes advantage of the natural (110) cleavage plane in zinc-blende III-V materials, eliminating this faceting.

### CROSS-REFERENCE TO RELATED APPLICATIONS

This application claims priority to and the benefit of U.S. Provisional Patent Application No. 63/196,897 filed on Jun. 4, 2022, the contents of which are incorporated herein by reference in their entirety.

### CONTRACTUAL ORIGIN

The United States Government has rights in this invention under Contract No. DE-AC36-08GO28308 between the United States Department of Energy and Alliance for Sustainable Energy, LLC, the Manager and Operator of the National Renewable Energy Laboratory.

### BACKGROUND

III-V solar cells exhibit higher conversion efficiencies than any other technology. However, high costs related to epitaxial growth and growth substrates limit the applications of III-Vs to high value applications like space. Hydride vapor phase epitaxy (HVPE) is a promising method to reduce the epitaxy costs associated with III-V solar cell growth. Epitaxial liftoff (ELO) with substrate reuse is the industry-standard substrate cost-reduction method. ELO uses a selectively-etched sacrificial layer between the substrate and the solar cell to release the substrate for reuse. ELO is proven commercially, but its cost competitiveness for terrestrial applications is limited by low throughput and the need for a chemical mechanical polishing (CMP) step to clear insoluble etch products. Current estimates of CMP costs are $10-$25 per wafer, too high for most terrestrial applications.

### SUMMARY

We present a study of the effect of hydride vapor phase epitaxy (HVPE) growth conditions on the morphology of GaAs grown on vicinal and nominally-exact (110) GaAs substrates. We evaluate epilayer surfaces using a combination of Nomarski microscopy and atomic force microscopy (AFM). The surface morphology strongly depends on the growth conditions employed, as well as the substrate orientation. On substrates offcut 3° towards (111)A, faceting generally develops under conditions in which the growth is Ga-limited, although Ga-limited growth is not only requirement for faceting. Low growth temperatures lead to a faceted morphology, while higher growth temperatures favor smooth growth and facet-free morphology. We show that the surface morphology is kinetically-controlled, and that the tendency to facet correlates with the growth rate. 3D growth occurs on nominally-exact substrates, resulting in hillock formation, but reduction of the group V precursor partial pressure results in smooth morphology. Overall, our results are consistent with models for step-bunching-induced surface faceting that invoke a negative Ehrlich-Schwoebel step-edge barrier.

In an aspect, provided is a method comprising: a) providing a GaAs substrate having a lattice orientation of (110), (110) offset 3° towards (111)A, or (110) offset 3° towards (111)B; b) depositing one or more lattice-matched semiconducting materials on the GaAs substrate via hydroxide phase vapor epitaxy (HVPE).

In another aspect, provided is an optoelectronic device comprising: a) a GaAs substrate having a lattice orientation of (110), (110) offset 3° towards (111)A, or (110) offset 3° towards (111)B; and b) one or more semiconducting materials lattice-matched to the GaAs substrate.

The lattice-matched semiconducting materials may comprise one or more III-V semiconductors, for example, GaAs or GaInP. The step of depositing may be performed at a temperature less than or equal to 750° C., 700° C., or optionally 650° C.

The step the step of depositing the one or more lattice-matched semiconducting materials may further comprise: i) flowing a group III source into a deposition chamber at a group III partial pressure; and ii) flowing a group V source into a deposition chamber at a group V partial pressure. The group III source may comprise GaCl or InCl, for example, GaCl or InCl generated in-situ by reacting metallic Ga or In with anhydrous HCl. The group V source may comprise AsH₃ or PH₃. The group V partial pressure may be less than or equal to 5 times, 4 times, 3 times or 2.5 times the group III partial pressure.

The GaAs substrate may be removable via controlled spalling and the described method may further comprise removing the GaAs substrate from the lattice matched semiconducting material. Advantageously, the facile removal of the GaAs substrate may be reused.

Other objects, advantages, and novel features of the present invention will become apparent from the following detailed description of the invention when considered in conjunction with the accompanying drawings.

### BRIEF DESCRIPTION OF THE DRAWINGS

FIG. 1A depicts GaAs growth rate as a function of GaCl partial pressure for growth on (110) 3A substrates. FIG. 1B and FIG. 1C depict Nomarski images of (110) 3A GaAs 31 and 60 μm/h growth rates, respectively. Scale bar is 20 μm.

FIG. 2 depicts Nomarski images of GaAs epilayers grown on on-axis (110) substrates with two different growth rates.

FIG. 3 depicts high-resolution x-ray diffraction of a GaInP epilayer grown on an on-axis (110) GaAs substrate.

FIGS. 4A and 4B depict EQE (FIG. 4A) and light J-V curves (FIG. 4B) for rear heterojunction GaAs solar cells grown on (110) and (100) substrates.

FIG. 5 depicts epilayer structure and Ω-2Θ scan of the GaAs/GaInP/GaAs epilayer structures disclosed herein.

FIGS. 6A, 6B, 6C, 6D, and 6E depict Nomarski microscopy images of GaAs (110) epilayers grown on 3A substrates with constant P_{GaCl}=1.2×10⁻³ atm and varying P_{AsH}_{₃} of (FIG. 6A) 2.8×10⁻⁴, (FIG. 6B) 3.7×10⁻³, (FIG. 6C) 4.9×10⁻³ and (FIG. 6D) 6.1×10⁻³ atm. The scale bars on all images are 5 μm. (FIG. 6E) Growth rate as a function of P_{AsH}_{₃} with constant P_{GaCl}=1.2×10⁻³ atm.

FIGS. 7A, 7B, 7C, 7D, and 7E depict Nomarski microscopy images of GaAs (110) epilayers grown on 3A substrates with constant P_{AsH}_{₃}=6.1×10⁻³ atm and varying P_{GaCl} of (FIG. 7A) 6×10⁻⁴, (FIG. 7B) 1.2×10⁻³, (FIG. 7C) 1.8×10⁻³ and (FIG. 7D) 2.4×10⁻³ atm. The scale bars on all images are 5 μm. (FIG. 7E) Growth rate as a function of P_{GaCl} with constant P_{AsH}_{₃}=6.1×10⁻³ atm.

FIGS. 8A and 8B depict Nomarski microscopy images of the GaAs (110) surfaces grown on 3A substrates with T_{D}=650° C., P_{AsH}_{₃}=2.8×10⁻³ atm, P_{GaCl}=1.2×10⁻³ atm and thickness of (FIG. 8A) 0.53 μm and (FIG. 8B) 3.6 μm min.

FIGS. 9A, 9B, 9C, and 9D depict (FIG. 9A) 10 μm×10 μm AFM images, (FIG. 9B) growth rate, (FIG. 9C) AFM [0001] line-scans, and (FIG. 9D) terrace width and facet height measured from the AFM line-scans in (FIG. 9C) as a function of growth temperature for samples grown on 3A substrates with P_{GaCl}=1.2×10⁻³ atm, P_{AsH}_{₃}=6.1×10⁻³ atm, and Q_{H2}(AsH₃)=3500 sccm. The error bars in (FIG. 9D) are standard deviations of six measurements of terrace width and facet height.

FIGS. 10A, 10B, 10C, and 10D depict Nomarski microscopy images of GaAs epilayers grown on (FIG. 10a) nominally-exact (110), (FIG. 10b) 3A and (FIG. 10c) 3B substrates. The growth conditions for all samples were the same: T_{D}=650° C., P_{GaCl}=1.2×10⁻³, P_{AsH}_{₃}=6.1×10⁻³ and Q_{H2}(AsH₃)=2500 sccm. (FIG. 10d) Nomarski image of a GaAs epilayer grown on a nominally-exact GaAs (110) substrate with the same conditions as FIGS. 10A-C except that Q_{H2}(AsH₃)=1500 sccm.

FIGS. 11A, 11B, and 11C depict Nomarski images of lattice matched GaAs/GaInP/GaAs structure grown on GaAs (110)3A substrate at Tg=650° C. and V/III=5 showing the morphological evolution as Q_{H2}(AsH₃) increases from 2500 to 3500 sccm (FIGS. 11A-C). Total system flow remained constant. Growth rate (GR) is listed above each image.

### DETAILED DESCRIPTION

Disclosed herein are methods and compositions that depict the effect of hydride vapor phase epitaxy growth conditions on the morphology of GaAs epilayers grown on vicinal and nominally exact (110) GaAs substrates. Adatom incorporation kinetics at step edges are shown to control the resultant surface morphology and can be manipulated to achieve smooth surfaces.

III-V semiconductor layers grown on (110) surfaces offer a number of desirable properties compared to those grown on commonly used (100) substrates. For example, III-V quantum wells on (110) substrates are attractive for spintronics applications due to a long spin lifetimes relative to those grown on (100) substrates. Additionally, in-plane polarization anisotropy of the optical transition in quantum wells grown on (110) substrates enables fabrication of optical polarizers or modulators. These particular applications make use of the tendency for (110) GaAs growth by molecular beam epitaxy (MBE) and organometallic vapor phase epitaxy (OMVPE) to facet due to step bunching. However, other (110) device applications, including solar cells, transistors, and lasers, would benefit from smooth, facet-free growth on this orientation. Smooth epitaxy on (100)-oriented substrates is relatively straightforward within a large range of growth parameters, but those parameters do not translate to the (110) surface, often producing faceted morphology and poor optoelectronic quality when used for growth on (110) substrates. The kinetics of adatom incorporation into preexisting steps produce morphological instabilities such as step bunching, mound formation, and step meandering that occur during the step flow growth mode on vicinal surfaces. Understanding how to control the morphology of (110) growth surfaces is key to unlocking device applications on this orientation.

Another benefit of producing devices such as solar cells on (110) substrates is that the (110) orientation promotes facile removal of devices from the parent substrate, enabling flexible devices and cost reduction via reuse of the expensive substrate. Smooth surface morphology results when mechanical processes like controlled spalling or cleavage of lateral epitaxial films for transfer (CLEFT) are applied to the (110) plane, which is the natural cleavage plane of zinc-blende III-V semiconductors. 10 This is in contrast to spalling of the more standard (100) surface, where fracture occurs along the (011) and (0-11) planes with crack propagation in the direction. The resulting facets that occur on the (100) orientation potentially require smoothing before substrate reuse, adding additional cost to the process. Inexpensive device exfoliation and substrate reuse enabled by the (110) orientation could enable more widespread use of III-V photovoltaics when paired with less expensive growth methods than those that are currently used today.

Hydride vapor phase epitaxy (HVPE) is a potential option for lower cost III-V growth. HVPE achieves high GaAs growth rates, at least 528 μm/h, which increase throughput and decrease time on tool without sacrificing material quality, leading to the potential for reduced costs of III-V based devices. There are no reports in the literature about controlling the surface morphology of III-V materials grown on (110) substrates by HVPE. Described herein are the factors that control the surface morphology of HVPE-grown GaAs on the (110) surface. We identify growth conditions for smooth GaAs and GaInP on (110) GaAs substrates offcut 3° towards either (111)A or (111)B as well as nominally-exact substrates. We find that careful choice of precursor partial pressures and growth temperatures limits the occurrence of faceting on the (110) orientation. We discuss the origin of growth instabilities such as step-bunching, faceting, and mound formation for HVPE growth on (110) substrates in the context of models that invoke Ehrlich-Schwoebel (ES) step-edge barriers.

Controlled spalling, whereby a device is rapidly exfoliated from the substrate via crystalline cleavage, offers an alternative with the promise of higher throughput and the potential to eliminate CMP.

Previous work on spalling of (100) GaAs revealed challenges related to faceting as the spall propagates along weaker {110} planes. Facets have peak to valley heights of 5 μm or more, which limits the cost effectiveness of spalling by wasting material and requiring extra processing steps, like CMP, before substrate reuse. A more elegant solution is to spall (110)-oriented GaAs devices from (110) GaAs substrates exploiting the weak and highly selective {110} GaAs cleavage planes.

Comparatively little is understood about the growth of high-performance devices on the (110) orientation relative to (100), however. 21.5% efficient (110) GaAs solar cells with AlGaAs passivation were demonstrated by organometallic vapor phase epitaxy (OMVPE), roughly equivalent to the best (100) OMVPE efficiencies of the time, but only 17% efficiency was reached in a (110) HVPE device. That HVPE device lacked heterobarrier passivation of modern III-V cell designs. In this work, we demonstrate HVPE-grown GaAs solar cells on (110) substrates with equivalent results to those grown on the standard (100) orientation.

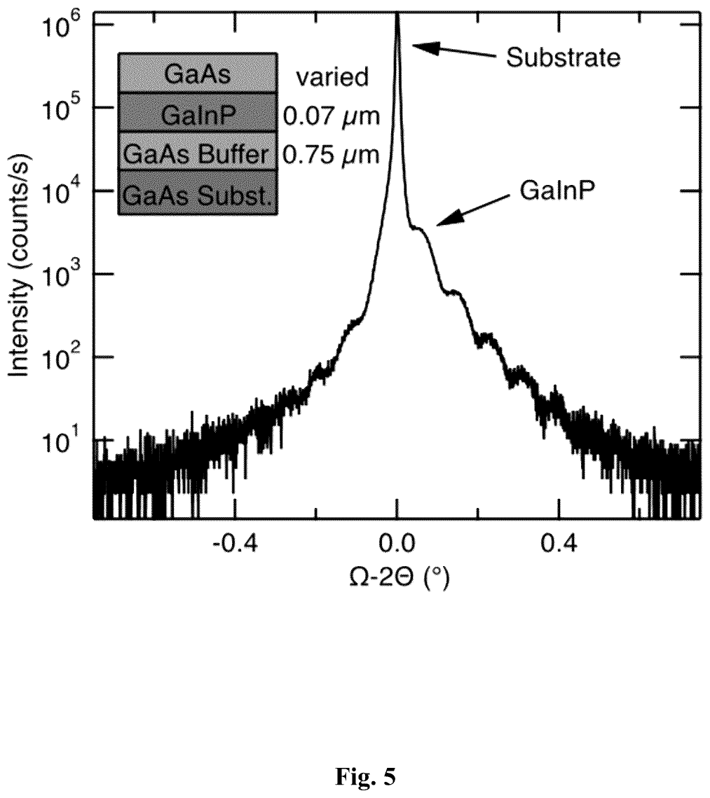

All materials were grown by atmospheric pressure HVPE using a single chamber with growth pauses between layers to set up the chemistry for the next layer. Substrates were GaAs with one of the following orientations: on-axis (110)±0.5°, (110) offcut 3° toward (111)A (3A), or (100) offcut 6° toward (111)A (FIG. 5A). GaAs and GaInP epilayers were grown to observe the effect of growth conditions on morphology and crystal quality. Nomarski microscopy and high-resolution x-ray diffraction were used to characterize the epilayers. GaAs rear heterojunction devices were grown with n-type absorbers and GaInP front window and back surface field layers. Devices with 0.25 cm² area were processed in an inverted fashion with Au broad-area rear contacts and one-sun, Au/Ni, photolithography-defined front grids.

External quantum efficiency (EQE) and reflectance were measured using calibrated photodiodes and a chopped white light source with a monochromator. Light current-density voltage (J-V) measurements were conducted using a Xe lamp and a reference cell to approximate an AM1.5G spectrum.

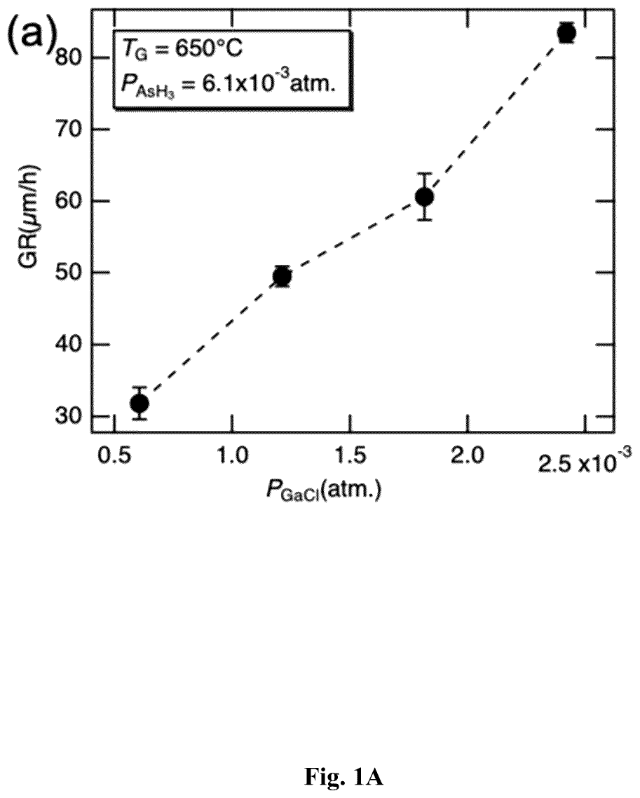

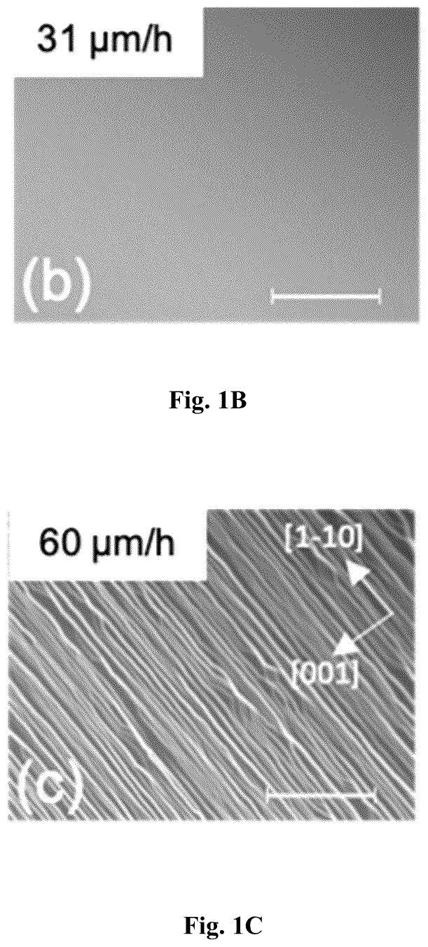

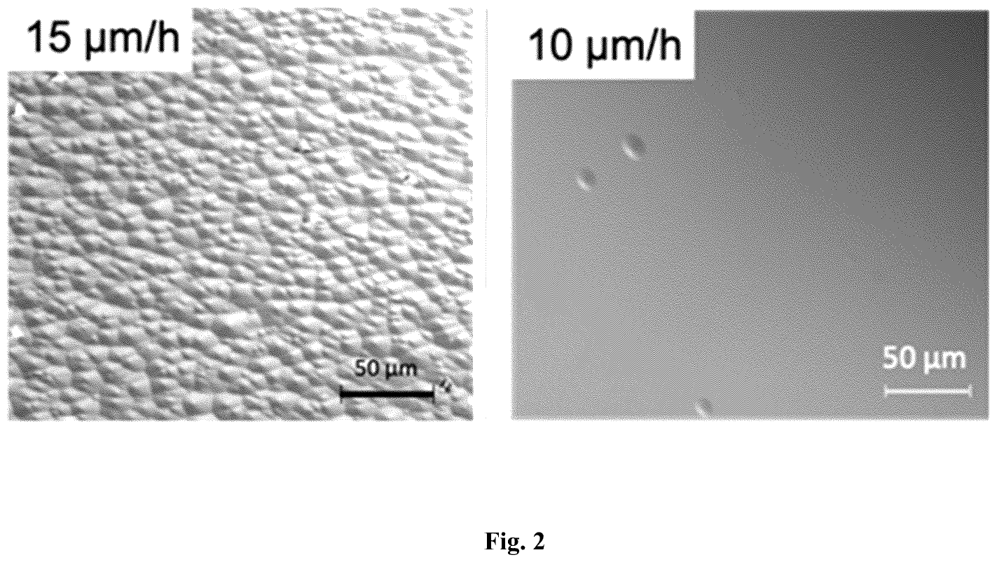

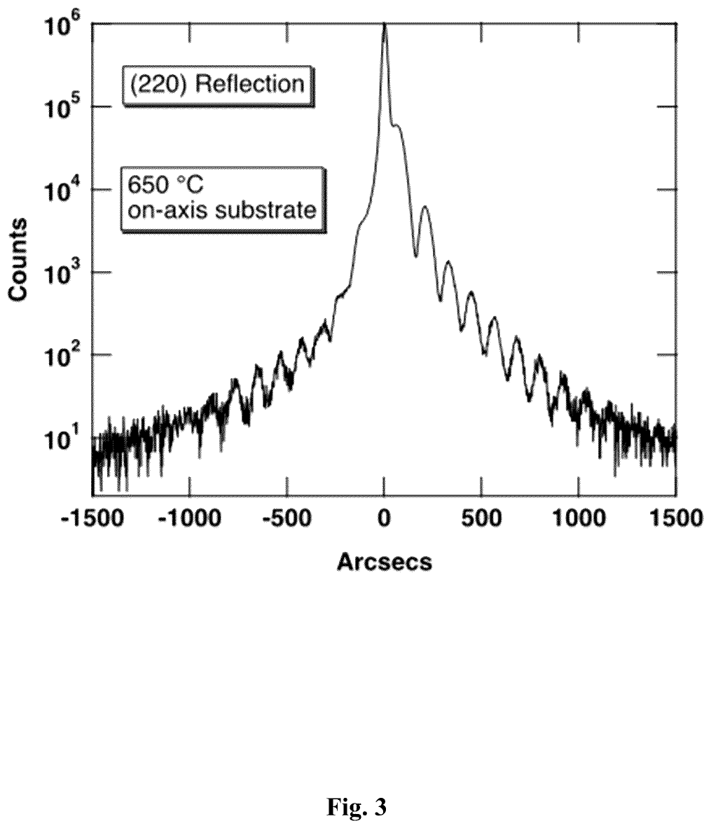

Initial growths revealed the optimal conditions for epitaxy on the (110) surface. FIG. 1(a) shows the growth rate as a function of the partial pressure of GaCl (P_{GaCl}) input to the growth zone for GaAs grown on (110) 3A GaAs at 650° C. The growth rate varied linearly with P_{GaCl}, reaching more than 80 μm/h. The surface morphology changed with the growth rate, however. FIGS. 1B and 1C compare Nomarski micrographs of samples grown at 31 μm/h and 60 μm/h. The higher growth rate sample exhibited a faceted morphology with steps parallel to [1-10]. We found that the morphology was controllable with careful choice of the partial pressures of the reactants and the growth temperature. The morphology of GaAs grown at 650° C. on on-axis (110) GaAs exhibited different morphology, as shown in FIG. 2. Initial growths exhibited 3D mound-like structure, which could be eliminated with similar control of the growth conditions. We also developed lattice matched n- and p-type GaInP layers for use as surface passivating windows and back surface field layers, respectively. FIG. 3 shows a high-resolution XRD scan of a Se-doped GaInP epilayer grown at 650° C. on an on-axis (110) substrate. The epilayer peak overlaps with the substrate, showing good lattice match, and the appearance of Pendellosung fringes implies a flat interface between the GaInP and GaAs.

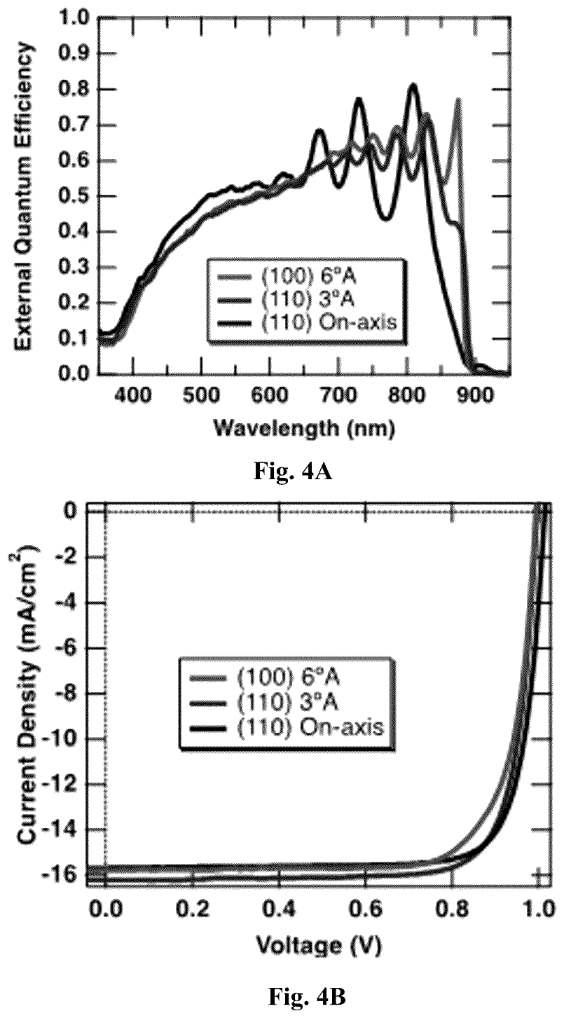

Next, we developed rear heterojunction GaAs solar cells on (110) 3A and on-axis substrates, as well as on our standard (100) 6A substrates as a control. FIG. 4 shows the EQE and J-V for these devices. These cells all have similar EQE and open-circuit voltage of ˜ 1.0 V implying that similar material quality was achieved on (110) and (100). The on-axis (110) cell was slightly thinner due to a lower growth rate, which affected the EQE shape. The control cell somewhat underperforms relative to our typical (100) GaAs solar cells, likely because of the use of growth pauses instead of dynamic HVPE growth. However, the essentially equivalent performance on all three substrate orientations highlights the promise (110) GaAs-based devices. Additional optimization will likely lead to better results.

All growths were performed at atmospheric pressure in our dual-growth-chamber HVPE system. GaCl and InCl, formed in-situ through the reaction of anhydrous HCl over Ga and In metals, were the group III sources, while AsH₃ and PH₃ were the group V sources. The source temperature where the metal chlorides are formed was held at 800° C. for all experiments. Substrates were p-type (110) GaAs, with either a nominally-exact orientation or 3° offcut towards (111)A or (111)B (referred to hereafter as ‘3A’ and ‘3B’). The effect of partial pressures of group III and V precursors on surface morphology was studied by varying the flow rates of these precursors. We note that, in our HVPE reactor, the amount of active group V precursor, i.e. uncracked hydride, is largely correlated with the amount of hydrogen carrier gas used to transport the precursor to the substrate surface. That is, higher hydrogen carrier flow leads to more uncracked hydride reaching the surface that can contribute to growth. We make use of this effect in specific experiments noted below to control the group V flux, in addition to changing the total amount of hydride input to the reactor in other experiments. Samples were grown at multiple different deposition temperatures (TD), varying between 625° C. and 700° C. Lattice-matched GaAs/GaInP/GaAs structures, which enabled determination of epilayer thickness by profilometry of selectively etched steps, were employed to determine growth rate for samples grown at 650° C. FIG. 5 shows the epilayer structure. We achieved smooth GaInP growth on (110) substrates at TD=650° C. and verified close lattice-matching to the substrate using high resolution x-ray diffraction. FIG. 5 also shows a representative Ω-2Θ scan of a GaAs/GaInP/GaAs structure. The root-mean square surface roughness (Rq) of the GaInP layer is <5 nm from a 5 μm×5 μm AFM scan. We kept the same growth conditions for the GaInP etch stop layer in all samples so that the surface morphology that the GaAs grows on remains the same. For samples grown at other growth temperatures (625° C. and 675-750° C.), n-type GaAs epilayers were grown directly on the p-type substrates, and epilayer thickness was measured by cross-sectional scanning electron microscopy by taking advantage of the contrast caused by the different dopants. Surface morphology was characterized by Nomarski contrast microscopy and atomic force microscopy (AFM) in the tapping mode.

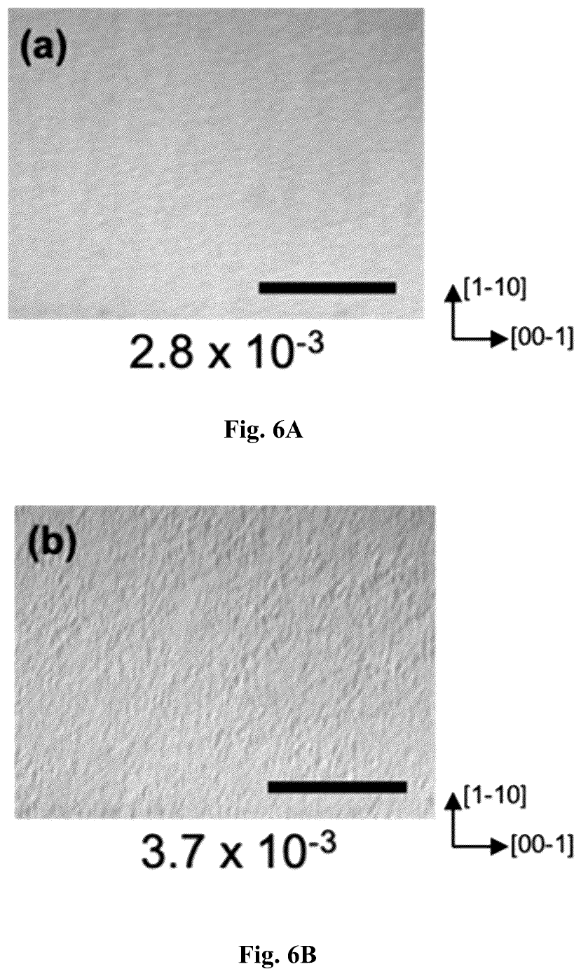

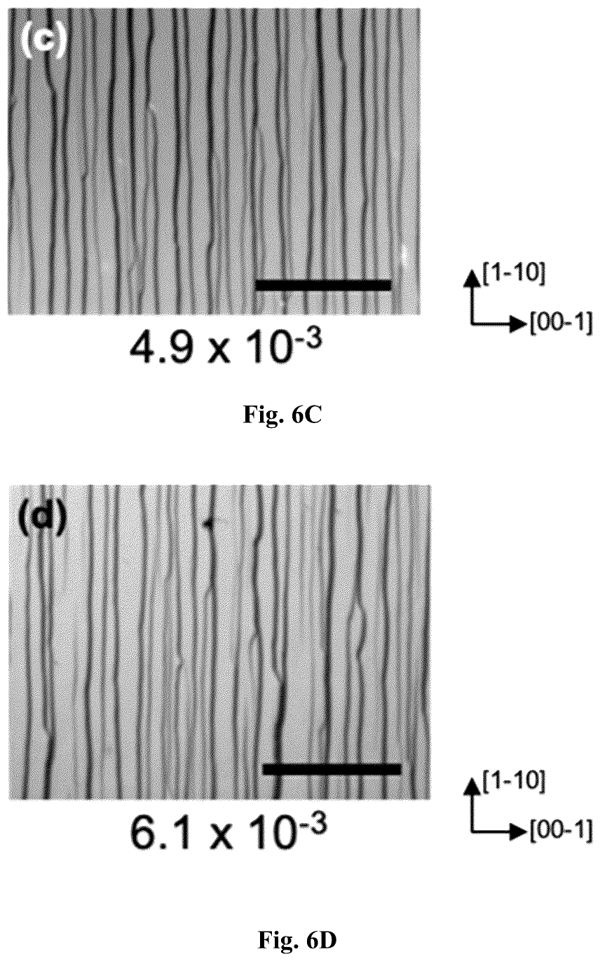

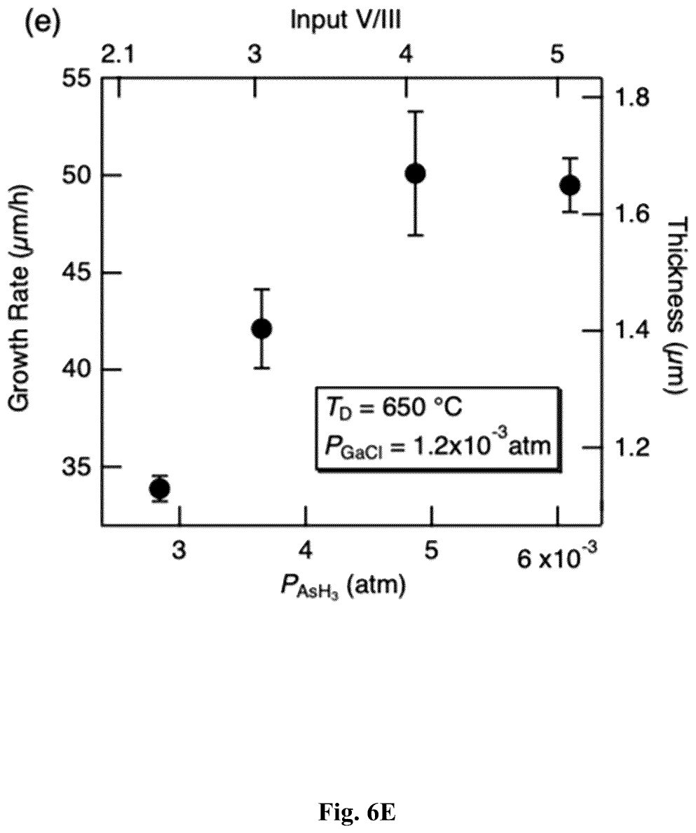

First, we investigated the effect of the partial pressures of AsH₃ (P_{AsH}_{₃}) and GaCl (P_{GaCl}) on the surface morphology of GaAs grown on 3A substrates. We set TD=650° C. and used a H₂ carrier gas flow rate through the AsH₃ inlet [Q_{H}_{₂}(AsH₃)]=3500 sccm for the top GaAs and Q_{H2}(AsH₃)=2500 sccm for the growth of the bottom GaAs layer in all cases. FIG. 6A-6D show Nomarski microscope images of epilayers grown with varying P_{AsH}_{₃} under constant P_{GaCl}=1.2×10⁻³ atm in the top GaAs layer. The Input V/III ratio, defined as the ratio of AsH₃ to HCl input to the Ga boat, is shown on the mirror x-axis, although we note that the precise As/Ga ratio on the surface is unknown. The surface was smooth at relatively low P_{AsH}_{₃}, but then exhibited a faceted morphology at higher P_{AsH}_{₃}, above an input V/III of about 3-4. The faceted morphology is similar to that observed during OMVPE19 and MBE growth of III-V materials on (110) substrates with a misorientation angle of 1.5-6° towards (111)A, where facets running parallel to the [1-10] direction form due to step bunching. FIG. 1E shows the growth rate as a function of P_{AsH}_{₃}. The growth rate increased with P_{AsH}_{₃}, initially, but then saturated for P_{AsH}_{₃}, ˜5×10⁻³ atm, suggesting that the growth became Ga-limited. The saturation in growth rate correlated with the appearance of surface faceting.

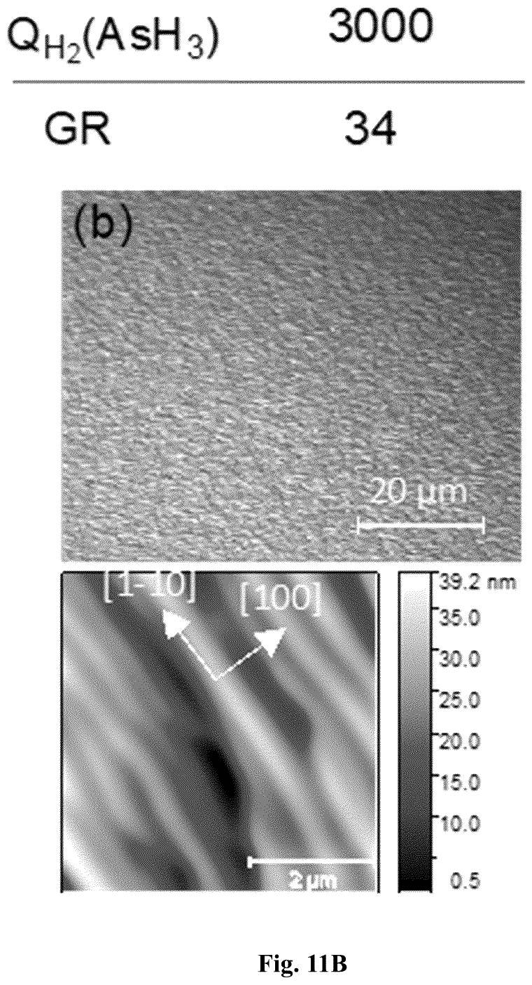

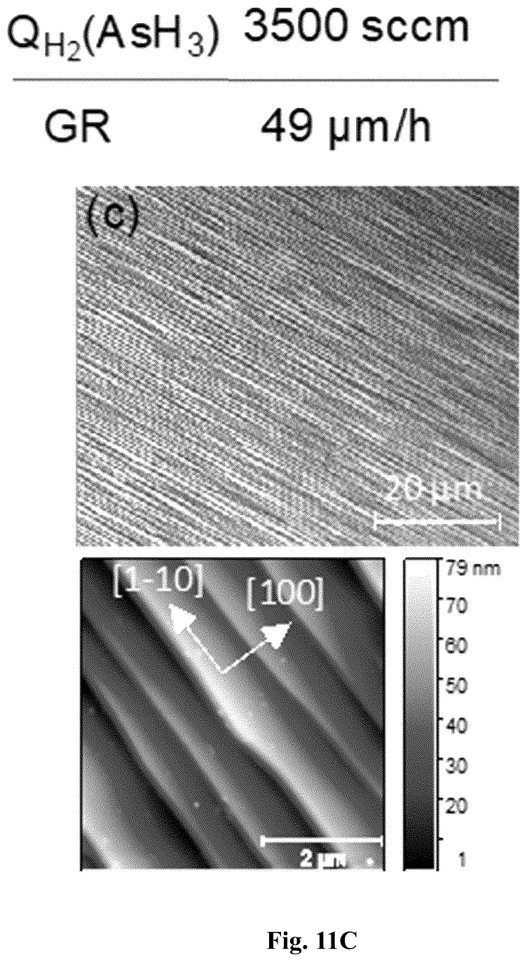

We investigated the effect of the AsH3 carrier gas on the surface morphology of the GaAs grown on (110)3A substrate by growing the lattice matched structure (GaAs/GaInP/GaAs) with V/III ratio=5 and at T_{g}=650° C. by varying the H₂ carrier gas flow rate through the AsH₃ inlet (QH₂(AsH₃)) from 2500 to 3500 sccm. The AsH₃ cracking rate is inversely proportional to QH₂(AsH₃). A previous study showed that delivery of uncracked AsH₃ to the sample surface with high QH₂(AsH₃) flow dramatically increases growth rate. A constant total system flow of 8260 sccm was maintained by removing an equal amount of flow from another reactor port so that the total H2 flow rate and reactant dilution level in the reactor remained constant. FIG. 11 shows the surface morphology and growth rate of three samples grown at different QH2(AsH3) on a (110)3A substrate. As QH₂(AsH₃) increases, the growth rate increases and a striking change in surface morphology is observed. This implies that a smooth morphology can be obtained by cracking a significant portion (or all) of the AsH₃.

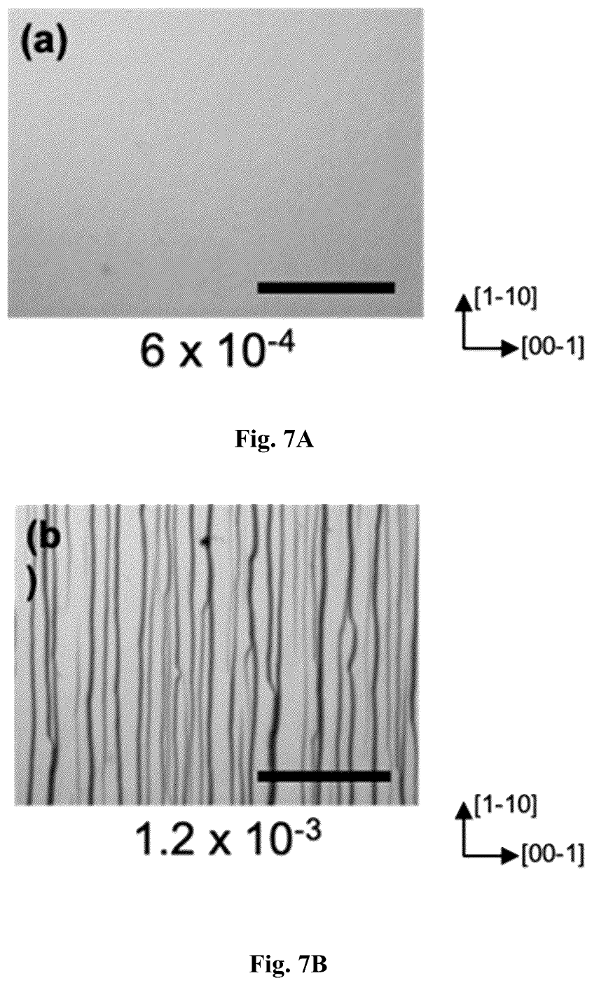

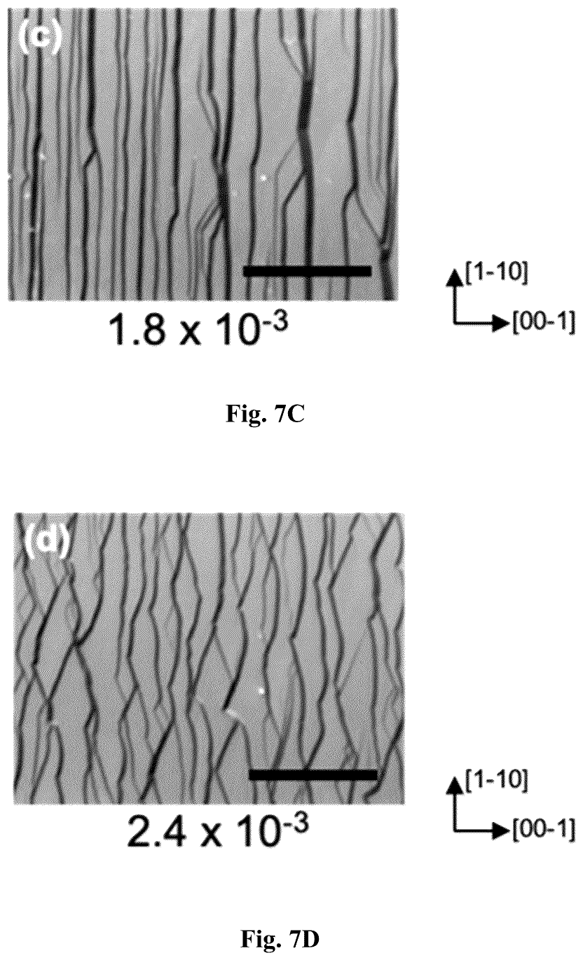

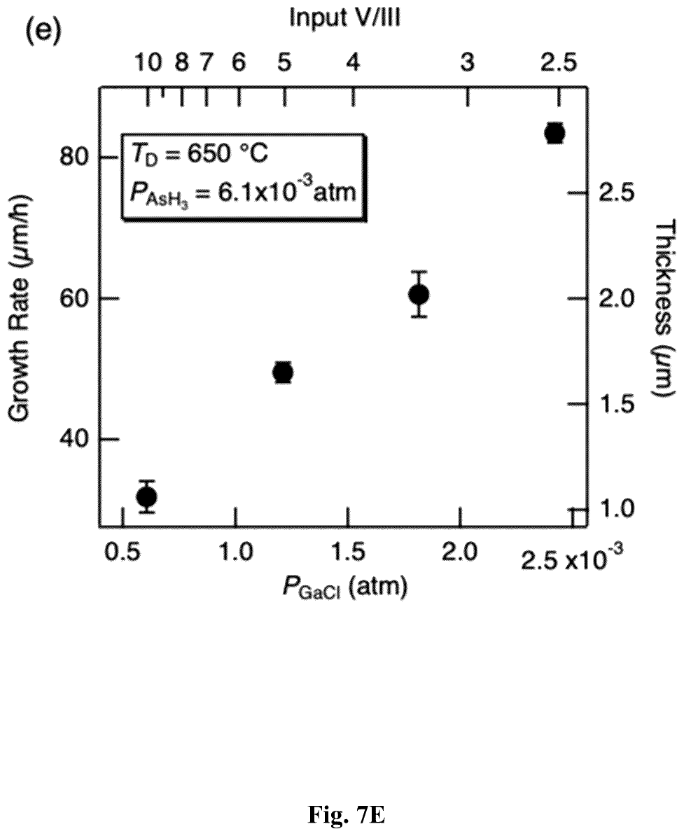

We then varied P_{GaCl} under constant P_{AsH}_{₃}, =6.1×10⁻³ atm, the highest AsH₃ value used in the initial sample set. FIGS. 7A-7D shows Nomarski images of the surface as a function of P_{GaCl}. The surface was smooth for the lowest P_{GaCl}, but facets appeared at higher P_{GaCl}. FIG. 7E plots the growth rate for these samples as a function of P_{GaCl}. The growth rate varied proportionally with P_{GaCl}, and did not exhibit saturation in this range. We note that the facets became wavy at the highest P_{GaCl}/growth rate used, consistent with the Bales-Zangwill instability. The results from FIGS. 6 and 7 suggest that Ga-limited growth is one requirement for the development of faceting. However, the fact that the smooth surface in FIG. 7A was obtained under Ga-limited growth indicates this is not the only requirement for faceting. It is unclear if the relatively high V/III used for that sample limited surface diffusion and faceting, or if faceting might have developed with more growth time and thickness.

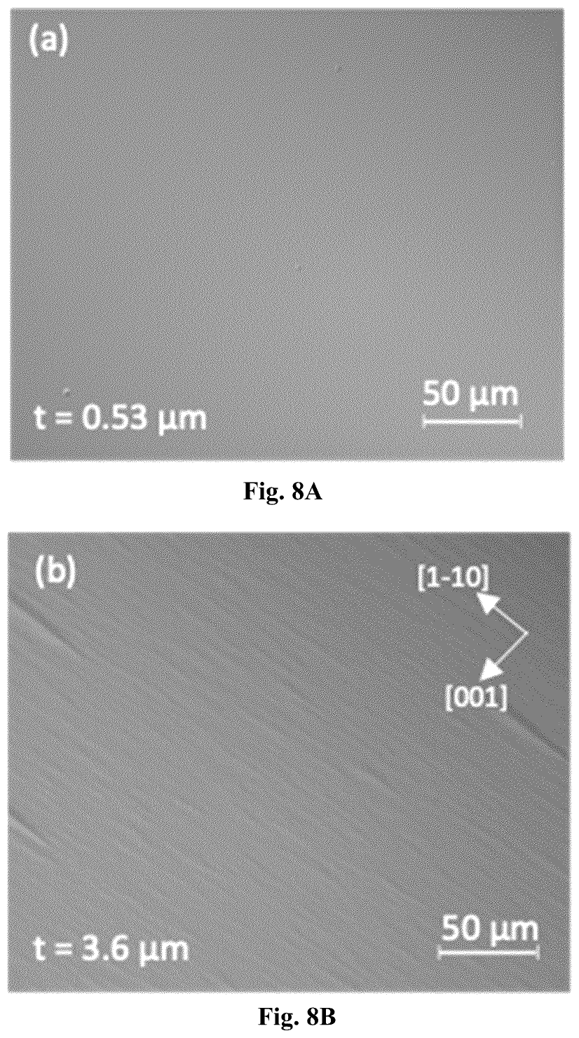

We note that the growth time was two minutes for the samples in these initial series, meaning that there was a difference in the final thickness of each of the layers. We studied the effect of thickness on surface morphology by growing two samples with the same growth conditions but with different final thicknesses. FIG. 8 shows Nomarski images of the surface morphology for samples with thicknesses of 0.53 μm (a) and 3.6 μm (b), respectively. The morphology was smooth in the thinner sample but began to show some signs of faceting as the thickness increased, suggesting that the faceting developed over time as the growth thickness increased. The growth rate was 32 μm/h for these conditions. We note that the samples with higher growth rates in FIGS. 1 and 2 show significantly more developed faceting than the sample in FIG. 8B, despite the fact that all of them were thinner. This suggests that the growth rate is a stronger factor than thickness in the determination of the surface morphology.

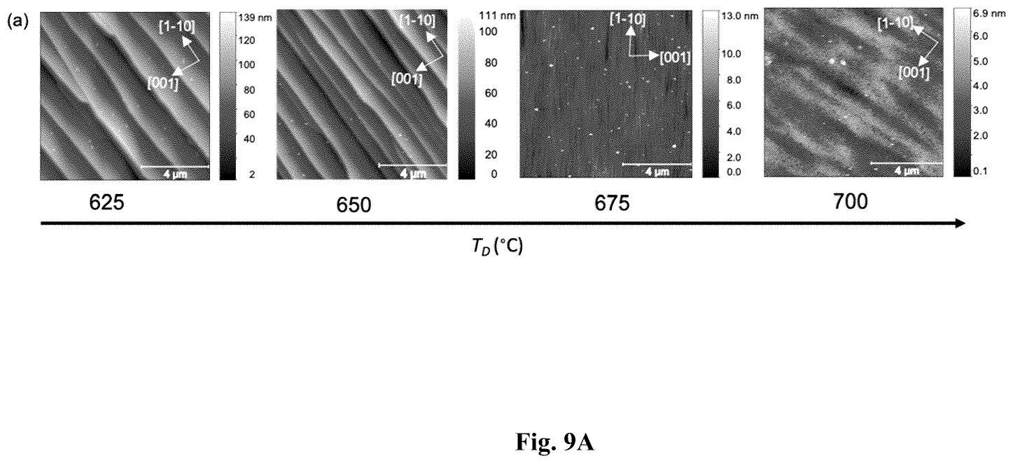

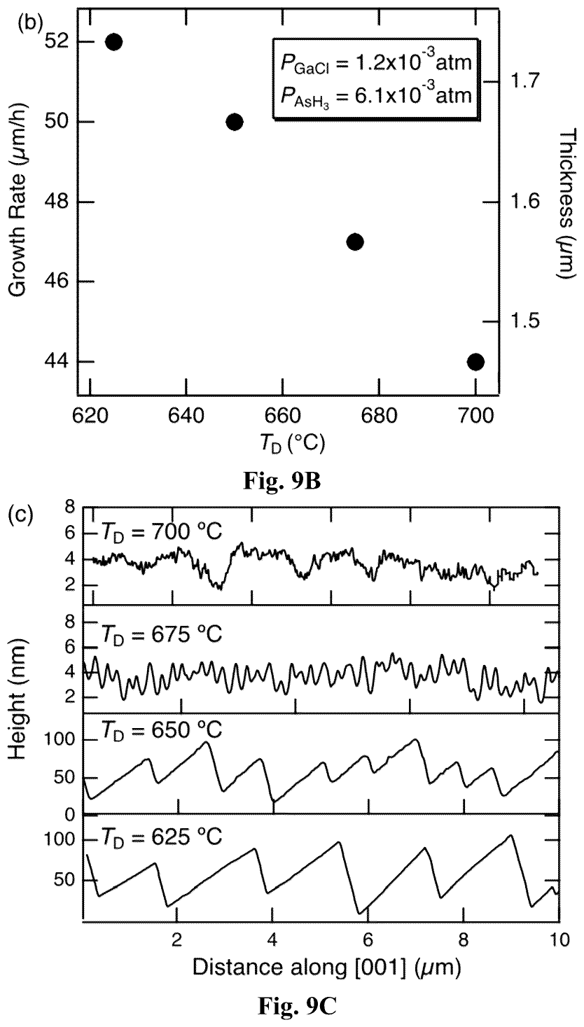

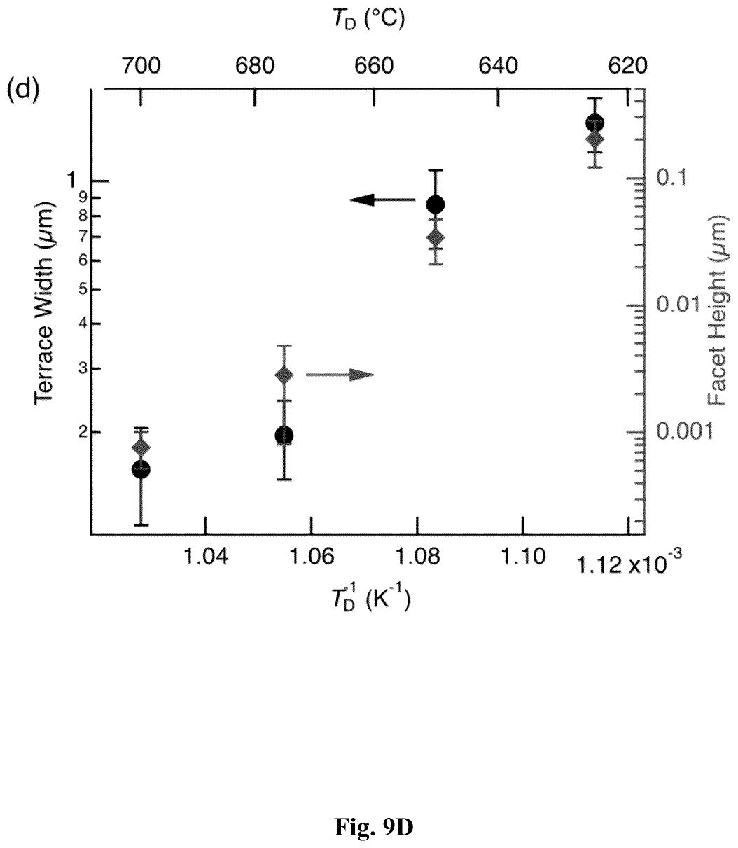

Next, we grew a series of samples with varying TD to observe the effect of that parameter on the surface morphology. We varied TD from 625° C. to 700° C. with QH₂(AsH₃)=3500 sccm, P_{GaCl}=1.2×10⁻³ atm, and P_{AsH}_{₃}=6.1×10⁻³ atm for all samples. The growth time for all of these samples was two minutes. FIG. 8A shows AFM scans of the surface morphology as a function of T_{D}. The surface morphology changed strongly with T_{D}, because samples grown with T_{D}>650° C. exhibited high roughness and faceting while the samples grown with T_{D}>650° C. were significantly smoother. FIG. 8B shows the growth rate measured for these samples. The growth rate decreased as a function of growth temperature, likely due to a combination of increased desorption of GaCl from the surface and increased cracking of AsH₃ at higher T_{D}. FIG. 8C shows linescans along acquired from the AFM scans that highlight the shape of the facets. The faceting exhibited smaller peak-to-valley heights and shorter periods as the temperature increased. FIG. 9D shows an Arrhenius plot of the average terrace width and facet height measured from the linescans. Both the terrace width and the facet height varied exponentially with temperature, implying that the surface morphology is kinetically-controlled, although we are not able to ascribe meaning to the apparent activation energies.

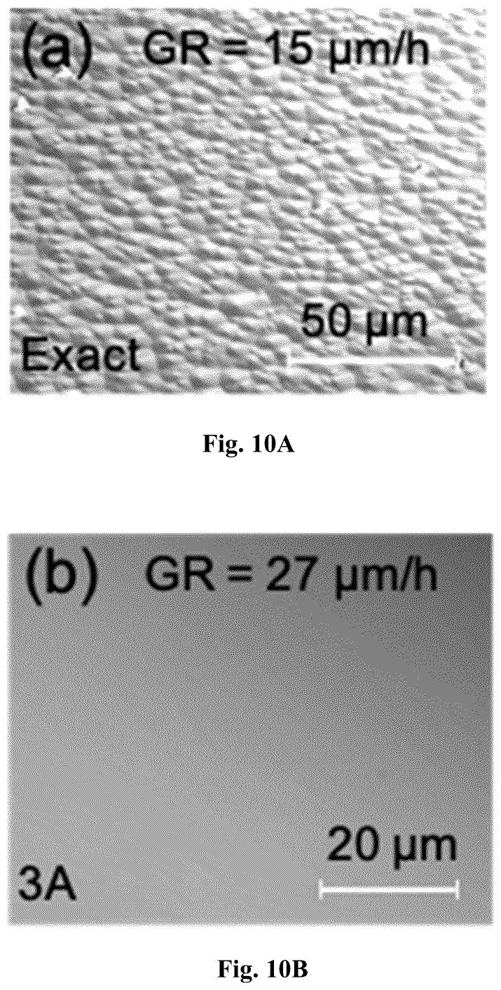

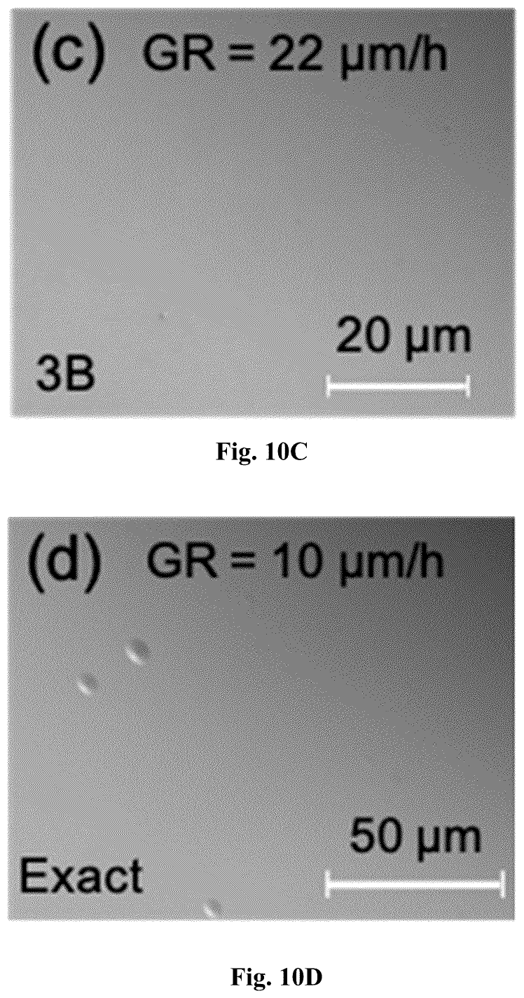

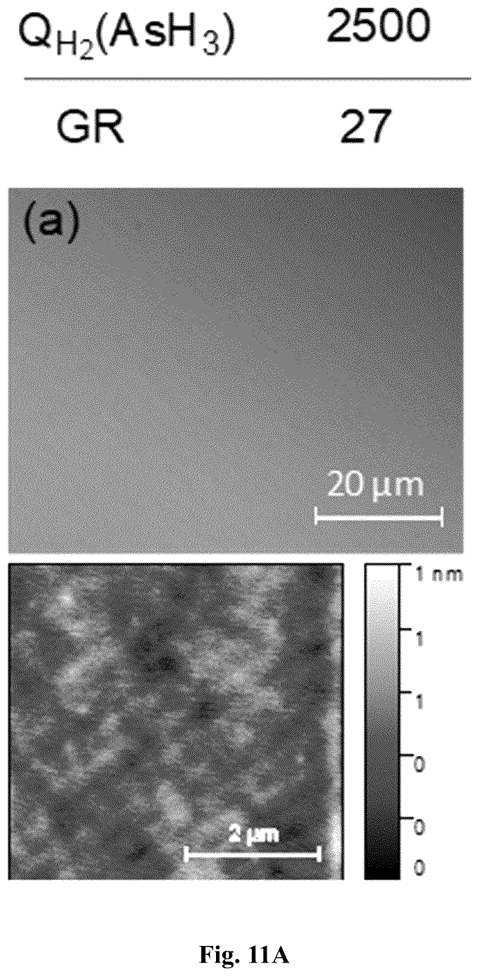

Finally, we investigated the effect of substrate offcut on the surface morphology by comparing growths on nominally-exact, 3A, and 3B (110) GaAs substrates. The samples were grown with T_{D}=650° C., Q_{H}_{₂}(AsH₃)=2500 sccm and, P_{AsH}_{₃}=6.1×10⁻³ atm and P_{GaCl}=1.2×10⁻³ atm. FIG. 10A shows that the layer grown on the nominally-exact (110) substrate is very rough and has the typical mounded morphology observed in the growth of III-V semiconductors this surface by OMVPE. In contrast, FIGS. 10B and 10C show the morphology of the epilayers grown on the offcut substrates is smooth regardless of the offcut direction. The growth rate was lower on the 3B substrate relative to the 3A, which could suggest differences in adatom attachment rates the B-type steps. We were able to grow a smooth sample on a nominally-exact (110) substrate using the same reactant flows as the sample in FIG. 10A but with reduced Q_{H}_{₂}(AsH₃)=1500 sccm, which increases the AsH₃ cracking and decreases the growth rate. FIG. 10D shows the surface morphology for the growth on this nominally-exact substrate using these conditions. The reduced gas-phase supersaturation led to a reduced growth rate of 10 μm/h. Higher supersaturation conditions may drive 3D island growth, leading to mound formation and the roughening observed in FIG. 10A.

Our observations of faceting on vicinal (110) surfaces are consistent with previous studies of (110) GaAs growth by MBE and OMVPE. Faceting of (110) GaAs was characterized on vicinal (110) GaAs substrates by MBE. It was observed that step-bunching and faceting occurred at low growth temperatures but that smoother step-flow growth occurred at high temperatures, just as we find here. Growth was Ga-limited at lower temperatures and As-limited at higher temperatures, due to increasing As desorption with temperature, which led them to explain their results by proposing the existence of positive and negative E-S step-edge barriers, respectively, for As and Ga adatoms at step edges. A positive E-S barrier is the additional barrier for an adatom to diffuse across a step edge down to a lower terrace and incorporate there. A negative E-S barrier implies that adatoms approaching step edges from upper terraces preferentially incorporate at those step edges vs. those that approach from the lower terrace. Positive E-S barriers are stable against step bunching because they cause the steps that lead wider terraces to advance more slowly than steps that lead narrower terraces. Negative E-S barriers are unstable to step bunching because the wider terraces advance faster than the narrower terraces, running into them. Thus, in MBE, step bunching and faceting occur when the growth is limited by the supply of Ga atoms and growth is smooth under As-limited conditions, attributed to the presence of step-edge barriers with opposite sign for each atom. We similarly observed that faceting tended to occur under conditions in which the growth was limited by Ga supply (see FIGS. 6 and 7). Following from previous literature then, an explanation for the occurrence of faceting in HVPE growth is that a similar negative E-S step-edge barrier exists for Ga adatoms, despite the use of a different Ga-precursor compared to MBE. The observed behavior with temperature is also consistent with kinetically-controlled faceting related to a step-edge barrier. Higher temperatures led to smoother surfaces presumably by enabling adatoms to overcome the effect of any step-edge barriers and incorporate more equally at steps on both sides of a terrace. It is also possible that increased desorption of AsH₃ relative to GaCl at higher temperatures reduced the effective V/III on the surface as the temperature increased, reducing the Ga-supply limitation. The use of relatively lower growth rates also resulted in smoother surfaces, though the kinetic explanation for this effect is less clear.

We note that positive E-S barriers are commonly cited as the cause of mound formation, so our observation of mounds in growth on nominally-exact surfaces may contradict the explanation that an inverse E-S barrier is present (although it was shown that this is not a necessary condition for the formation of mounds). Furthermore, some doubt about the plausibility of negative E-S barriers led researchers to develop models that predict similar faceting behavior in the presence of positive E-S barriers. Depending on the model, it has been shown that faceting may occur if there is an imbalance in step-catalyzed decomposition rates for precursors approaching from upper vs. lower terraces, or if there is a positive E-S barrier for precursor molecules but no barrier for their decomposed products. Faceting was also predicted to occur in the absence of any E-S barrier if there is a barrier to incorporation for adatoms approaching from lower terraces vs. upper terraces. Whether the barrier is truly positive or negative, the key is that the effective behavior approximates that of a simple negative E-S barrier to create the observed faceting. Our results clearly show that the HVPE surface morphology is kinetically-controlled, and that growth instabilities can be suppressed by careful control of the growth conditions and/or the surface misorientation. These results inform the development of HVPE-grown devices on (110) substrates at high deposition rates, even on nominally-exact orientations on which deposition was historically difficult.

We studied the growth of GaAs and lattice-matched GaInP on vicinal and nominally-exact GaAs (110) substrates by HVPE, demonstrating control over surface morphology. Surface faceting generally occurred under conditions where the growth was limited by Ga-supply. The surface morphology transitioned from faceted to smooth with increasing temperature. Faceting correlated with higher growth rate, generally occurring at rates >40 μm/h. We obtained smooth surfaces at lower growth rates on both offcut and nominally-exact-oriented (110) substrates. Surface morphology was kinetically-controlled, and the observed trends in faceting are consistent with kinetic models for adatom incorporation at step edges that invoke negative E-S barriers. The results presented here enable the development of HVPE-grown devices on (110) substrates.

The foregoing disclosure has been set forth merely to illustrate the invention and is not intended to be limiting. The terms and expressions which have been employed herein are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments, exemplary embodiments and optional features, modification and variation of the concepts herein disclosed may be resorted to by those skilled in the art, and that such modifications and variations are considered to be within the scope of this invention as defined by the appended claims. The specific embodiments provided herein are examples of useful embodiments of the present invention and it will be apparent to one skilled in the art that the present invention may be carried out using a large number of variations of the devices, device components, methods steps set forth in the present description. As will be obvious to one of skill in the art, methods and devices useful for the present methods can include a large number of optional composition and processing elements and steps.

As used herein and in the appended claims, the singular forms “a”, “an”, and “the” include plural reference unless the context clearly dictates otherwise. Thus, for example, reference to “a cell” includes a plurality of such cells and equivalents thereof known to those skilled in the art. As well, the terms “a” (or “an”), “one or more” and “at least one” can be used interchangeably herein. It is also to be noted that the terms “comprising”, “including”, and “having” can be used interchangeably. The expression “of any of claims XX-YY” (wherein XX and YY refer to claim numbers) is intended to provide a multiple dependent claim in the alternative form, and in some embodiments is interchangeable with the expression “as in any one of claims XX-YY.”

When a group of substituents is disclosed herein, it is understood that all individual members of that group and all subgroups, are disclosed separately. When a Markush group or other grouping is used herein, all individual members of the group and all combinations and subcombinations possible of the group are intended to be individually included in the disclosure. For example, when a device is set forth disclosing a range of materials, device components, and/or device configurations, the description is intended to include specific reference of each combination and/or variation corresponding to the disclosed range.

Every formulation or combination of components described or exemplified herein can be used to practice the invention, unless otherwise stated.

Whenever a range is given in the specification, for example, a density range, a number range, a temperature range, a time range, or a composition or concentration range, all intermediate ranges and subranges, as well as all individual values included in the ranges given are intended to be included in the disclosure. It will be understood that any subranges or individual values in a range or subrange that are included in the description herein can be excluded from the claims herein.

All patents and publications mentioned in the specification are indicative of the levels of skill of those skilled in the art to which the invention pertains. References cited herein are incorporated by reference herein in their entirety to indicate the state of the art as of their publication or filing date and it is intended that this information can be employed herein, if needed, to exclude specific embodiments that are in the prior art. For example, when composition of matter is claimed, it should be understood that compounds known and available in the art prior to Applicant's invention, including compounds for which an enabling disclosure is provided in the references cited herein, are not intended to be included in the composition of matter claims herein.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. In each instance herein any of the terms “comprising”, “consisting essentially of” and “consisting of” may be replaced with either of the other two terms. The invention illustratively described herein suitably may be practiced in the absence of any element or elements, limitation or limitations which is not specifically disclosed herein.

All art-known functional equivalents, of any such materials and methods are intended to be included in this invention. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

1. A method comprising:
providing a GaAs substrate having a lattice orientation of (110), (110) offset 3° towards (111)A, or (110) offset 3° towards (111)B; and
depositing one or more lattice-matched semiconducting materials on the GaAs substrate via hydroxide phase vapor epitaxy (HVPE).

2. The method of claim 1, wherein the lattice-matched semiconducting material comprises one or more III-V semiconductors.

3. The method of claim 1, wherein the lattice-matched semiconducting material comprises GaAs or GaInP.

4. The method of claim 1, wherein the step of depositing the one or more lattice-matched semiconducting materials is performed at a temperature less than or equal to 750° C.

5. The method of claim 1 wherein the step of depositing the one or more lattice-matched semiconducting materials further comprises:
flowing a group III source into a deposition chamber at a group III partial pressure; and
flowing a group V source into a deposition chamber at a group V partial pressure.

6. The method of claim 5, wherein the group III source comprises GaCl or InCl.

7. The method of claim 6, wherein the group III source is generated in-situ by reacting anhydrous HCl with Ga or In.

8. The method of claim 5, wherein the group V source comprises AsH₃ or PH₃.

9. The method of claim 5, wherein the group V partial pressure is less than or equal to 4 times the group III partial pressure.

10. The method of claim 1, wherein the GaAs substrate has a (110) lattice orientation.

11. The method of claim 1, further comprising:
removing the GaAs substrate from the lattice matched semiconducting material via controlled spalling.

12. The method of claim 1, wherein the GaAs substrate is reusable.

13. The method of claim 1, further comprising:
generating an optoelectronic device.

14. An optoelectronic device comprising:
a GaAs substrate having a lattice orientation of (110), (110) offset 3° towards (111)A, or (110) offset 3° towards (111)B; and
one or more semiconducting materials lattice-matched to the GaAs substrate.

15. The optoelectronic device of claim 14, wherein the one or more semiconducting materials comprise:
a GaAs buffer layer proximate to the GaAs substrate;
a GaInP layer proximate to the GaAs buffer layer; and
a third GaAs layer proximate to the GaInP layer.

16. The optoelectronic device of claim 14, wherein the GaAs substrate has a lattice orientation of (110).

17. The optoelectronic device of claim 14, wherein the GaAs substrate is removable via controlled spalling.

18. The optoelectronic device of claim 14, wherein the GaAs substrate is reusable.
